(19) United States
(12) Patent Application Publication
(10) Pub. No.: US 2024/0427098 A1
(43) Pub. Date: Dec. 26, 2024

(54) ANALOG OPTICAL INTERCONNECT FOR ANALOG SENSING AND PROCESSING

(71) Applicant: UNIVERSITY OF SOUTHERN CALIFORNIA, LOS ANGELES, CA (US)

(72) Inventors: Akhilesh JAISWAL, Los Angeles, CA (US); Ajey P. JACOB, Los Angeles, CA (US); Sujith CHANDRAN, Los Angeles, CA (US); Md ABDULLAH-AL KAISER, Los Angeles, CA (US)

(21) Appl. No.: 18/824,636

(22) Filed: Sep. 4, 2024

Related U.S. Application Data
(63) Continuation of application No. PCT/US2023/014625, filed on Mar. 6, 2023.
(60) Provisional application No. 63/316,739, filed on Mar. 4, 2022.

(51) Int. Cl. G02B 6/43; G02B 6/293; G02B 6/42; H04B 10/80; H10B 10/00; H10B 63/10; H10B 80/00

(52) U.S. Cl. CPC G02B 6/43; G02B 6/29301; G02B 6/2934; G02B 6/4215; H04B 10/801; H10B 80/00; H10B 10/00; H10B 63/10

(57) ABSTRACT

Provided is a device, including: an analog optical interconnect; an input array coupled to the analog optical interconnect; and an analog or mixed signal processor or a memory array coupled to the input array via the analog optical interconnect.

### CROSS-REFERENCE TO RELATED APPLICATIONS

This application claims benefit of U.S. Provisional Patent Application 63/316,739 titled APPARATUS AND METHOD FEATURING ANALOG OPTICAL INTERCONNECTS FOR ANALOG SENSING AND PROCESSING, filed 4 Mar. 2022. The entire contents of each aforementioned patent filing is hereby incorporated by reference.

### BACKGROUND

### 1. Field

The present disclosure relates generally to optical interconnects.

### 2. Description of the Related Art

Optical interconnects may be used to send signals between integrated circuits or portions thereof using light—such as by phase modulation, amplitude modulation, frequency modulations, etc. Some forms of such interconnects are expected to afford advantages over electrical interconnects such as lower latency, lower power consumption, higher bandwidth, ability to multiplex data, etc. Sensors, such as sensors containing pixels (for example, image sensors), may require transfer of large amounts of data—e.g., pixels of still images, video frames, etc.—from the sensing device to a processing device for further data processing (such as facial recognition, motion detection, etc.) including via machine learning algorithms.

### SUMMARY

The following is a non-exhaustive listing of some aspects of the present techniques. These and other aspects are described in the following disclosure.

Some aspects include a device, comprising an analog optical interconnect; an input array coupled to the analog optical interconnect; and an analog or mixed signal processor or a memory array coupled to the input array via the analog optical interconnect.

Some aspects include a selector configured to connect the input array to the analog optical interconnect.

Some aspects include a selector configured to connect the analog optical interconnect to the processor or memory array.

Some aspects include an integrated circuit comprising the device.

Some aspects include a method of analog optical communication between an input array and a analog or mixed signal processor or a memory array.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 is a schematic representation of an analog optical interconnect, according to some embodiments;

FIG. 2A is an example schematic representation of an input analog device integrated with an example analog optical interconnect, according to some embodiments;

FIG. 2B is an example schematic representation of an input analog device with correlated double sampling integrated with an example analog optical interconnect, according to some embodiments;

FIG. 3 is an example schematic representation of an analog electro-optical transducer in an example analog optical interconnect, according to some embodiments;

FIG. 4A is an example schematic representation of an analog device to receive output integrated with an example analog optical interconnect, according to some embodiments;

FIG. 4B is an example schematic representation of a resistive random-access memory (RRAM) analog device to receive output integrated with an example analog optical interconnect, according to some embodiments

FIG. 4C is an example schematic representation of a static random-access memory (SRAM) analog device to receive output integrated with an example analog optical interconnect, according to some embodiments;

FIG. 4D is an example schematic representation of an analog device with correlated double sampling to receive output integrated with an example analog optical interconnect, according to some embodiments;

FIG. 5 is an example schematic representation of a phase-based analog electro-optical transducer in an example analog optical interconnect, according to some embodiments; and

FIG. 6 illustrates an example computing system using an analog optical interconnect, according to some embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the image detection and image processing. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

The description that follows includes example systems, methods, techniques, and operation flows that illustrate aspects of the disclosure. However, the disclosure may be practiced without these specific details. For example, this disclosure refers to specific types of memory (e.g., SRAM, RRAM (or ReRAM), random-access memory (RAM), dynamic RAM (DRAM), embedded DRAM (eDRAM), magnetoresistive RAM (MRAM), phase-change RAM (PCRAM), ferroelectric RAM (FeRAM), read only memory (ROM), etc.), specific types of transistors and materials (p-channel metal-oxide-semiconductor (pMOS), complementary metal-oxide-semiconductor (CMOS), etc.), specific types of transducers (e.g., electro-optical transducers, ring resonator transducers, phase-change transducers, etc.) in illustrative examples. Aspects of this disclosure may instead be practiced with other or additional types of memory, transistors, materials, and transducers. Additionally, aspects of this disclosure may be practiced with other types of optical sources (e.g., lasers, broadband sources) and photosensors (e.g., optical detector, photodiode, etc.) and sensors which are not photosensors. Further, well-known structures, components, instruction instances, protocols, and techniques have not been shown in detail to not obfuscate the description.

Many forms of data communication between CMOS (complementary metal-oxide-semiconductor) image sensors (or other image sensors or other types of sensors) and memory or a processor are relatively slow and power hungry. Such communication may have a high bandwidth requirement, such as due to transmission needs for multiple sensors (e.g., pixels). Optical interconnects may assist with these issues (such as with optical multiplexing to increase available transmission bandwidth), but many forms of optical interconnects involve analog to digital conversions (e.g., of signals), which may be slow, power-intensive, etc. and may cause a bottleneck in data transmission (which is not to suggest that any technique is disclaimed).

Implementing an analog optical interconnect between an image sensor (e.g., a CMOS image sensor, an analog sensor array, etc.) and further processing or storage, such as at a memory or processor (e.g., a central processing unit, a microcontroller, a graphical processing unit, machine-learning co-processor (such as a computer-vision co-processor), or the like) may facilitate significant bandwidth reduction, energy efficiency, increase data transmission speed, etc. This approach, in some embodiments, may eliminate or reduce analog-to-digital (ADC) and digital-to-analog (DAC) conversions between the transceiver nodes (e.g., transmission nodes and receiver nodes) and, in some embodiments, may facilitate analog processing, such as analog in-memory/pixel computation. An analog signal may be a signal which is not quantized or processed for quantization (in full or in part)—such as by an ADC or DAC. An analog signal may include portions which are quantized (or digitalized) or portions which have values which correspond to digital values (e.g., 0, 1, etc.) but which have not been quantized to produce such values. In some embodiments, an analog signal may not be quantized by a receiver of the signal on the analog optical interconnect (for example, at a buffer, by an optical transducer, etc.), for instance, until after subsequent downstream processing. In some embodiments, such signals are not subject to analog-to-digital conversion between the sensor (or input array) and the receiver (or memory or processor array) on the analog optical interconnect, for instance, until after subsequent downstream processing.

Some embodiments may implement an analog optical interconnect which acts as communication link between analog sensors (or processor) to analog processors (such as analog mixed signal accelerators) or arrays thereof. Components of some embodiments may include one or more the following:
a. an analog optical connection;
b. a pixel array or other input array, which may be an analog device or array;
c. an analog crossbar array or other memory or processor array, which may receive data from the input array;
d. a column selector, which may be a sample and hold (S/H) column selector, or other method of selecting an element of an array for input or to receive output;
e. a row selector, which may be an S/H row selector, or other method of selecting an element of an array for input or to receive output;
f. a timing control unit, which may be a time division multiplexing unit or other time sampling unit, or additional control which may synchronize the array to receive output of the input array with the input array;
g. a buffer amplifier array, or other buffer or amplifier; and
h. one or more amplifier, which may be a transimpedance amplifier (TIA).

The structure of some embodiments may include one or more of the following:
a. one or more analog sensor (which may be an array of pixels or other sensor units), such as a CMOS image sensor (or processor), connected through one or more analog optical interconnects to one or more analog signal processing unit(s), which may include mixed signal processing unit(s) such as both an analog optical interconnect and a digital interconnect (which may be electrical, optical, parallel to the analog optical interconnect, in series with the analog optical interconnect, etc.);
b. a CMOS image sensor or other sensor with correlated double sampling (CDS) circuits (e.g., operations) on a sensor (e.g., input) or processor (e.g., output) side of one or more optical analog interconnects;
c. a CMOS image sensor or other sensor with analog in-pixel computing connected to analog, mixed signal processing by one or more analog optical interconnect;
d. one or more analog optical connection, which may include a micro-ring (e.g., active micro-ring, micro-ring resonator, etc.) connected to a photodetector, including connected by a cascade connection to the photodetector; and
e. one or more analog optical connection, which may include a symmetric or asymmetric Mach-Zehnder interferometer, including connected by a cascade connection to a photodetector.

In operation, some embodiments may implement one or more of the following processes:
a. an ADC-free (e.g., a substantially analog) transfer of data from CMOS image sensors over one or more analog optical interconnects;
b. a combination (e.g., substantially in parallel, in series, or in another appropriate arrangement) of one or more analog optical interconnects and ADC (e.g., a low-resolution ADC, a low power ADC, an ADC applied to output of fewer than all sensors or pixels, etc.) for digital and analog data transfer through optical interconnects (e.g., analog and digital optical interconnects, transmission of digital signal via analog optical interconnects, etc.);
c. a DAC-free (e.g., a substantially analog) transfer of data from CMOS image sensor over one or more analog optical interconnects;
d. a combination (e.g., substantially in parallel, in series, or in another appropriate arrangement) of one or more analog optical interconnects and DAC (e.g., a low-resolution DAC, a lower power DAC, an intermittently sampling DAC) for digital and analog data transfer through optical interconnects (e.g., analog and digital optical interconnects, transmission of digital signal via analog optical interconnects, etc.);
e. a method of performing one or more CDS operations with analog optical interconnects; and
f. a method of incorporating analog in-pixel computing with analog optical interconnects.

Some embodiments are expected to afford the following advantages over other approaches, though it again should be emphasized that embodiments are not limited to systems that afford all of these advantages, which is not to suggest that any other description is limiting:
a. higher speed
b. higher energy efficient
c. single transmission in analog domain
d. computation in analog domain
e. significantly lower bandwidth requirement

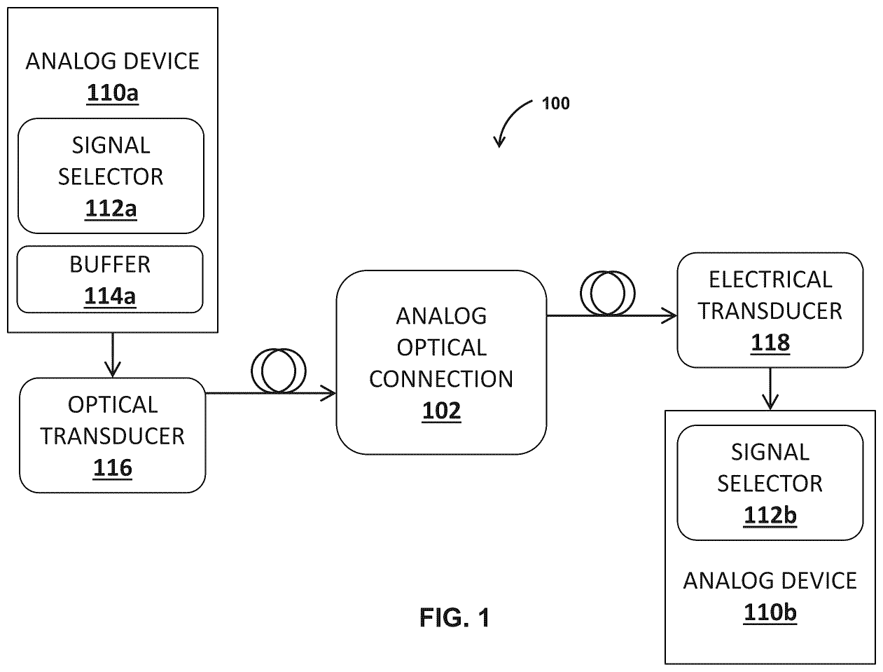

FIG. 1 is a schematic representation of an analog optical interconnect 100. The analog optical interconnect 100 is depicted as integrated with an analog device 110a, which provides input, and an analog device 110b, which receives output. The analog device 110a and 110b may be integrated with the analog optical interconnect 100, or may be separate from the analog optical interconnect 100. The analog device 110a may be an array of sensors, including optical or image sensors. The analog device 110a may include a signal selector 112a or be in communication with the signal selector 112a. The analog device 110a may include a buffer 114a or be in communication with the buffer 114a. The buffer 114a may include one or more amplifiers. The signal selector 112a may select a signal (or sensor of the analog device 110a which produces a signal) for output. The signal selector 112a may transmit the signal from the analog device 110a to the buffer 114a. Alternatively, or in addition, the buffer 114a or another buffer or one or more amplifiers may operate on the signal before it is selected by the signal selector 112a. The selected signal from the analog device 110a is then transmitted to an optical transducer 116. The selected signal may be an electrical signal. The selected signal may be another type of signal, such as a microwave signal. The selected signal may be an analog signal. The selected signal may include one or more digital signals, such as encoded with an analog signal, instead of an analog signal, etc. The selected signal may contain both analog and digital portions, included different types of signals during different portions of a transmission cycle.

The optical transducer 116 may be multiple optical transducers, such as a set of micro-ring resonators. The optical transducer 116 may be any appropriate optical transducer, such as a resonator, a phase-change based transducer, etc. The optical transducer 116 may receive an optical input, such as via an optical bus, which is altered by the optical transducer 116 due to application of the selected signal. The optical transducer 116 may contain a multiplexing unit, such as for multiplexing output of multiple optical transducers. The optical transducer may receive an electrical input, such as voltage, current, power, etc. The optical transducer 116 may be integrated into the analog device 110a or otherwise in communication with the analog device. The optical transducer 116 may be heterogeneously integrated with the analog device 110a, such as through packaging traces. The optical transducer 116 may be part of a packaging or interconnect package which receives input from or supports the analog device 110a.

Output of the optical transducer 116 may travel over one or more analog optical connection 102, which may be an optical waveguide, optical fibers, etc. The analog optical connection 102 may receive optical signals from one or more analog devices, including the analog device 110a. The analog optical connection is depicted as transmitting signals from the analog device 110a to the analog device 110b, but may also or instead transmit signals from the analog device 110b to the analog device 110a or from a portion of the analog device 110a to another portion of the analog device 110a. The analog optical connection 102 may include one or more signal splitter, reflector, signal multiplexer, signal demuxer, signal amplifier, etc.

The analog optical connection 102 may transmit optical signals to one or more electrical transducer 118. The electrical transducer 118 may be any appropriate electrical transducer, such as a photodetector, a photodiode, etc. The electrical transducer 118 may include one or more amplifier. The electrical transducer 118 may transduce (e.g., transform) the optical signal from the analog optical connection 102 into an electrical signal. The electrical transducer 118 may instead (or additionally) be another type of transducer (such as a microwave transducer). The electrical transducer 118 may be integrated with the analog device 110b. The electrical transducer 118 may be integrated with the analog optical connection 102. The electrical transducer 118 may be in communication with the analog device 110b. The electrical transducer 118 may be in communication with a signal selector 112b, which may be integrated with or in communication with the analog device 110b. The signal selector 112b may determine, such as based on timing in a timing cycle, based on signal identifiers, etc., a destination (e.g., within the analog device 110b) for a given electrical signal received from the electrical transducer 118. The signal selector 112b may be in communication with the signal selector 112a, such as through the analog optical interconnect, via a clock (not depicted), etc. The signal selector 112b may select a destination for a given signal and cause switching of one or more electrical element of the analog device 110b (e.g., via a row selector, via a column selector, etc.) such that the given signal is stored or processed at a given location of the analog device 110b.

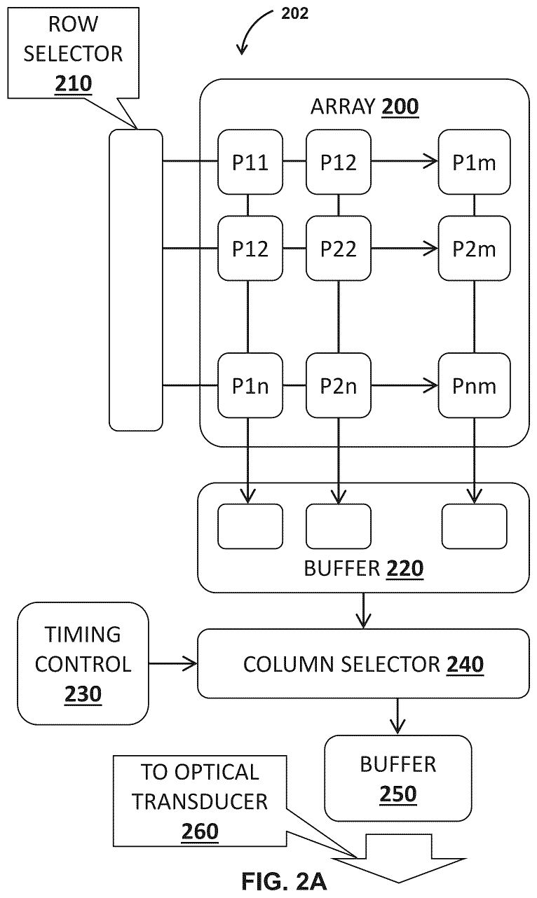

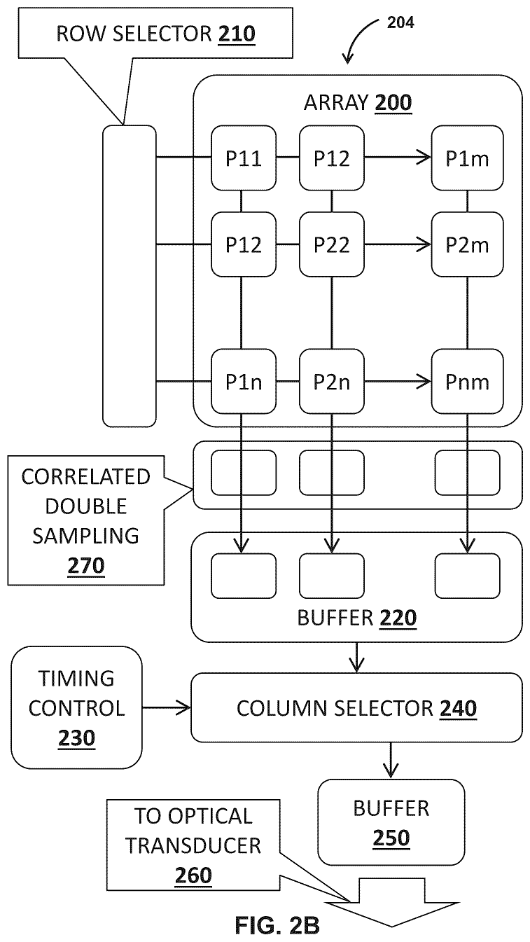

FIG. 2A is an example schematic representation of an input analog device 202 integrated with an example analog optical interconnect. The input analog device 202 may be the analog device 110a of FIG. 1. The input analog device 202 may be an analog sensor device. The input analog device 202 may be a mixed signal sensor device (e.g., may output both analog and digital signals). The input analog device 202 may be or contain analog or mixed signal processing, such as circuitry for analog signal processing, circuitry for digital signal processing, circuitry for analog and digital signal processing. The input analog device 202 may be a signal accelerator, including an accelerator which incorporates one or more element of a neural network, processing of a neural network, a kernel of a neural network, including elements described in in PCT Application PCT/US2023/0011531 filed 25 Jan. 2023, titled EMBEDDED ROM-BASED, MULTI-BIT, MULTI-KERNEL, MULTI-CHANNEL WEIGHTS IN INDIVIDUAL PIXELS FOR IN-PIXEL COMPUTING, and U.S. Provisional Patent Application 63/433,592, filed 19 Dec. 2022, titled PERIPHERAL CIRCUITS FOR PROCESSING IN-PIXEL, the entire contents of each aforementioned patent filing is hereby incorporated by reference.

The input analog device 202 may contain one or more sensors (e.g., image sensors), which may be optical sensors, pixels, etc. The sensors of the input analog device 202 may be arranged in an array 200. The array 200, for example, may contain pixels P11-Pnm arranged in a two-dimensional array. The array 200 may instead or additionally contain a point array, one-dimensional array, a three-dimensional array, etc. The array 200 may contain pixels corresponding to photodetectors. The pixels may contain sub-pixels containing photodetectors with different wavelength detection ranges. The pixels may instead or additionally be other sensors, such as force sensors, infrared (IR) sensors, temperature sensors, etc. Individual elements (e.g., pixels) of the array 200 may be selected, such as for detector (e.g., biased on) or for output (e.g., selected for signal output) by operation of a row selector 210 and a column selector 240. The row selector 210 and the column selector 240 may be any appropriate signal selection device or operation, such as the signal selector 112a of FIG. 1.

The input analog device 202 may contain a timing control unit 230, which may control the operation of the row selector 210 and the column selector 240. The timing control unit 230 may add identifiers to signals output by the input analog device 202. The timing control unit 230 may receive signals from or be in communication with a control unit for the input analog device 202. The timing control unit 230 may operate based on one or more clocking signals, including a clocking signal for the input analog device 202. The timing control unit 230 may generate a clocking signal.

The input analog device 202 may contain one or more buffers, such as a buffer 200 which may buffer column output before application of the column selector 240 and a buffer 250 which may buffer output of the column selector 240. The one or more buffer may instead or additionally be an amplifier, including a TIA. The output of the input analog device 202 may be output to an optical transducer (e.g., via an output to optical transducer 260), such as the optical transducer 116 of FIG. 1.

FIG. 2B is an example schematic representation of an input analog device 204 with correlated double sampling integrated with an example analog optical interconnect. The input analog device 204 is described in reference to elements previously described in reference to the input analog device 202 of FIG. 2A, but may contain any appropriate circuitry. The input analog device 204 may contain circuitry for correlated double sampling (CDS) such as a correlated double sampling (CDS) unit 270. The CDS unit 270 may include any appropriate circuitry for CDS, such as switches, comparators, memory, etc. The CDS unit 270 may compare output of a sensor of the array 200 to output of another sensor of the array 200, to a previous output of the given sensor, etc. The CDS unit 270 may compare outputs of sensors, pixels, sub-pixels, etc. The CDS unit 270 may compare outputs of multiple of sensors, pixels, sub-pixels—for example may compare outputs of columns of sensors. The CDS unit 270 may compare voltage outputs, may compare current outputs, etc. The CDS unit 270 may instead or additional include array level computations, such as addition, multiplication, cross-product, etc. of output of multiple sensors. The CDS unit 270 may instead be another comparison unit, such as those described in U.S. Provisional Patent Application 63/395,725, filed 5 Aug. 2022, titled IRIS: INTEGRATED RETINAL FUNCTIONALITY IN IMAGE SENSORS and U.S. Provisional Patent Application 63/478,468, filed 4 Jan. 2023, titled PROCESSING-IN-PIXEL-IN-MEMORY FOR NEUROMORPHIC IMAGE SENSORS, the entire contents of each aforementioned patent filing is hereby incorporated by reference.

In some embodiments, the array 200 may include pixels which contain in-pixel processing, computing, etc. The array 200 may include pixels which contain memory, including ROM, RAM, RRAM, DRAM, etc. The array 200 may include circuitry which corresponds to one or more kernel. The array 200 may include circuitry which applies weighting to outputs of pixels, such as weighting corresponding to weights of one or more nodes of a neural network. The array 200 may include circuitry which configures the pixels to act as neurons of a neural network. The array 200 may include any appropriate accelerator circuitry, such as that described previously.

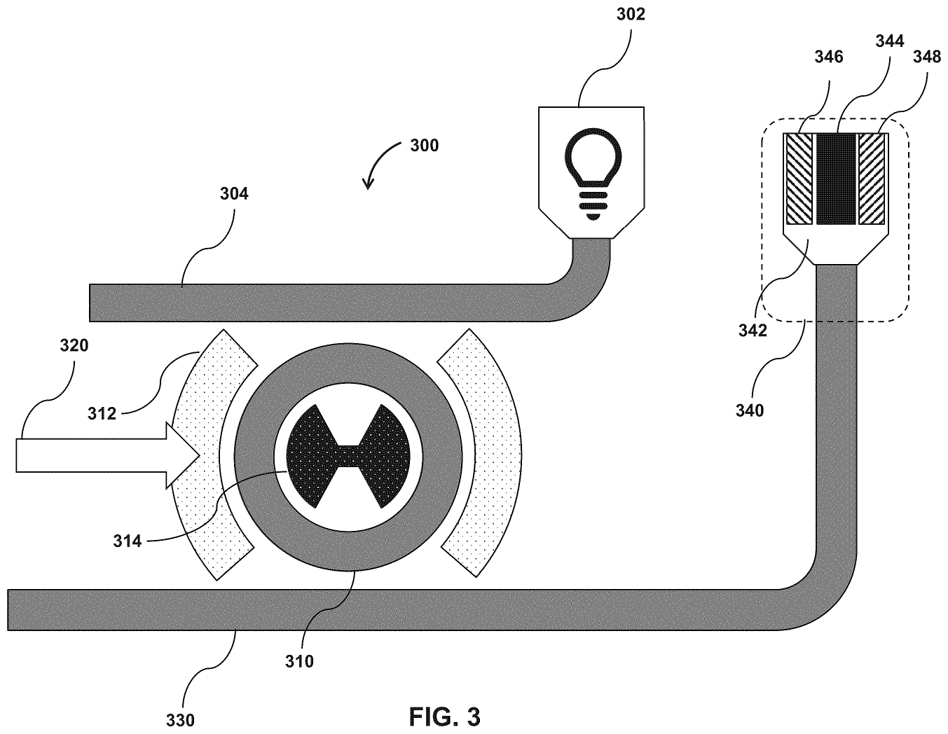

FIG. 3 is an example schematic representation of an analog electro-optical transducer 300 in an example analog optical interconnect. The analog electro-optical transducer 300 may also transduce digital signals. The analog electro-optical transducer 300 may contain an optical source 302, which may be a laser, a broadband optical source, etc. The optical source 302 may be an integrated optical source, such as a laser source fabricated on a silicon chip. The optical source 302 may be a fixed optical source. The optical source 302 may be a sweeping optical source, or otherwise capable or in communication with a device capable of altering the wavelength or wavelength distribution of the optical source 302. The optical source 302 may provide an optical signal to a waveguide 304. The waveguide 304 may be any appropriate waveguide, such as a silicon bus waveguide. The waveguide 304 may be an integrated waveguide, such as a recessed waveguide in a silicon chip. The waveguide 304 may be an optical fiber and may be integrated, such as through V-groove integration, with a substrate.

The waveguide 304 may provide an optical signal to an optical selector, such as a ring (or micro-ring) resonator 310. The ring resonator 310, or another optical selector, may select, such as through a resonator filter, one or more signal from the waveguide 304. The signal selected by the ring resonator 310 may have a narrow bandwidth than the signal produced by the optical source 302. The ring resonator 310 may operate substantially only if the optical signal in the waveguide 304 contains a signal corresponding to the resonance frequency (or wavelength) of the ring resonator 310. For example, if the optical source 302 is outside of the wavelength for which the ring resonator 310 operates (e.g., is excited or operates in transmission mode) the ring resonator 310 may not operate to allow transmission (e.g., may be opaque to the optical signal). The ring resonator 310 may, for certain wavelengths (frequencies), transmit an optical signal from the waveguide 304 to a waveguide 330. The waveguide 330 may be a drop waveguide, such as a silicon drop waveguide. The resonant frequency of the ring resonator 310 may be adjusted by application of a signal (e.g., an electrical signal) to contacts of the ring resonator 310. The ring resonator 310 may be in communication with (e.g., through in plane fabrication, output of plane fabrication, via doped regions, via one or more metal contact, etc.) contacts which, when an electrical signal is applied, alter the optical path length of the ring resonator 310. The ring resonator 310 may, for example, have a first contact 312, which may be a p-contact or p-doped region of a semiconductor such as that in which the ring resonator 310 is fabricated. The ring resonator 310 may have a second contact 314, which may be an n-contact or n-doped region of a semiconductor, such as that in which the ring resonator 310 is fabrication. An electrical signal, such as the output of the input analog device 202 of FIG. 2A or the input analog device 204 of FIG. 2B, may be applied, such as by input 320, to one or more contact of the ring resonator (e.g., the first contact 312, the second contact 314, etc.). The input may be applied to one contact while a second contact is grounded, electrically isolated, or otherwise has applied a constant or variable voltage, current, charge, etc. The ring resonator 310 may have capacitive contacts. The ring resonator 310 may be altered by heating, such as by resistive contacts.

The ring resonator 310 may have a resonant wavelength (frequency) altered by application of the electrical signal to the ring resonator 310, such as due to alteration of the optical path length (e.g., changing of a depletion region width, alteration of free carrier concentration, etc.). The application of the electrical signal to the ring resonator 310 may change an output of the ring resonator 310, such as to the waveguide 330. The application of the electrical signal to the ring resonator 310 may change a wavelength (frequency) transmitted along the waveguide 330. The application of the electrical signal to the ring resonator 310 may change whether or not a wavelength is transmitted along the waveguide 330—or an amplitude of the wavelength as so transmitted. For example, the application of the electrical signal to the ring resonator 310 may move the resonant wavelength of the ring resonator 310 from outside a wavelength range of the optical source 302 (in a case where the ring resonator 310 would be substantially opaque to the optical source 302) to inside a wavelength range of the optical source 301 (in a case where the ring resonator 310 would transmit a wavelength (or range of wavelengths) of the optical source). The ring resonator may operate as a filter, such as described in U.S. Provisional Patent Application 63/333,801, filed 22 Apr. 2022, titled APPARATUS AND METHOD FOR VIRAL DETECTION USING RING RESONATOR BASED SPECTROMETRY, the entire contents of each aforementioned patent filing is hereby incorporated by reference.

Wavelengths transmitted along the waveguide 330 may be detected at a photodetector 340. The photodetector 340 may be any appropriate photodetector, including a photodiode. The photodetector 340 may have any appropriate wavelength range, such as a wavelength range corresponding to that of the optical source 302. The photodetector 304 may detect one or more static wavelength ranges, may sweep across a wavelength range, etc. The photodetector 340 may be integrated into a semiconductor wafer, such as into a silicon slab (including a silicon slab which contains one or more integrated laser, waveguide, etc.). The photodetector 340 may contain an active region 344, such as a germanium (Ge) active region. The photodetector 340 may contain one or more contacts, such as a first contact 346, which may be a p-contact or p-doped region of silicon or another semiconductor, and a second contact 348, which may be an n-contact or n-doped region of silicon or another semiconductor. The photodetector 340 may function as an electrical transducer, such as the electrical transducer 118 of FIG. 1. An electrical signal may be output by any appropriate contact of the photodetector 340, such as the first contact 346 or the second contact 348.

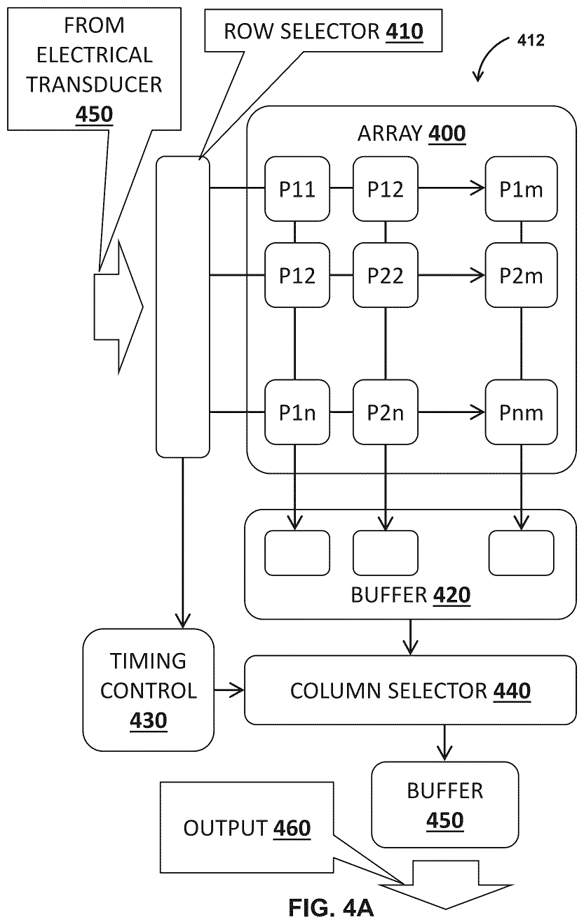

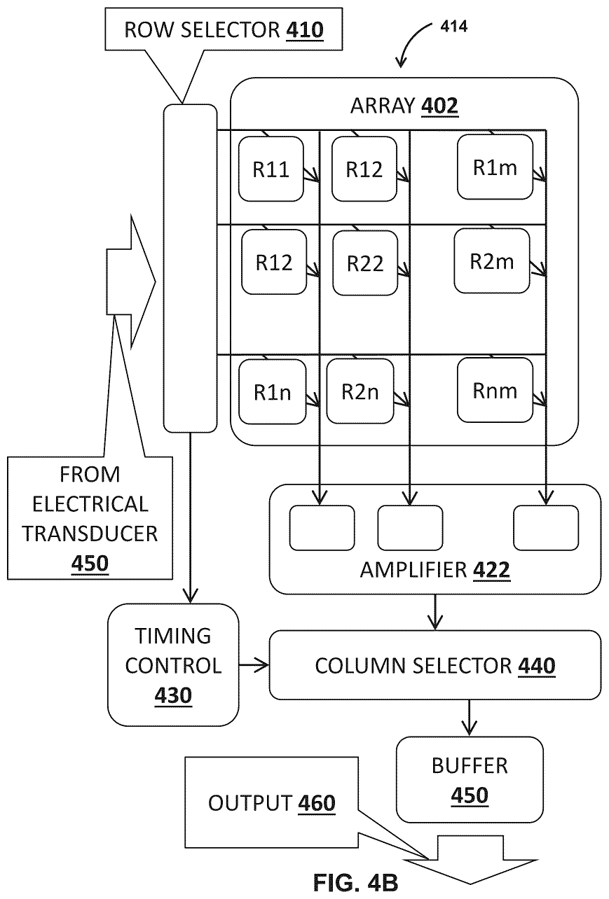

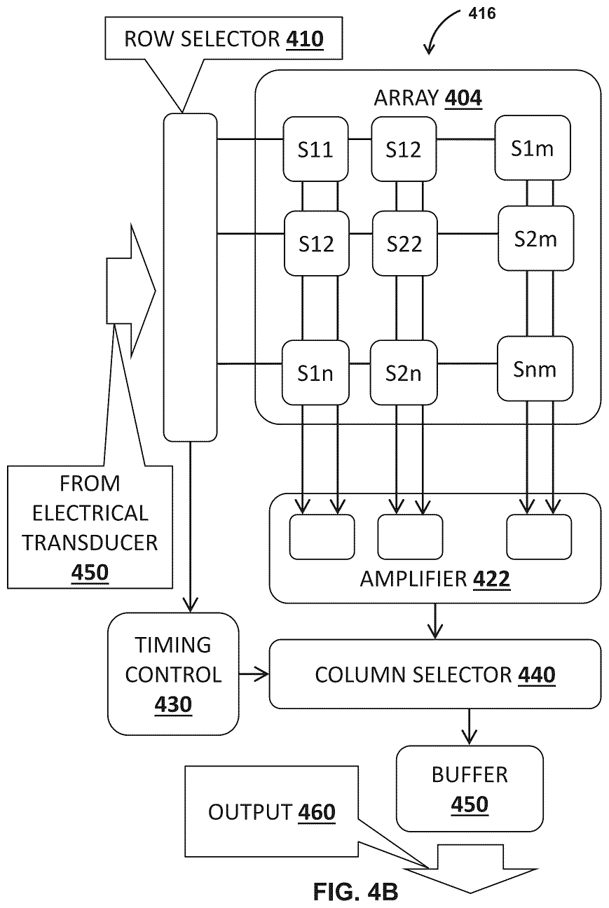

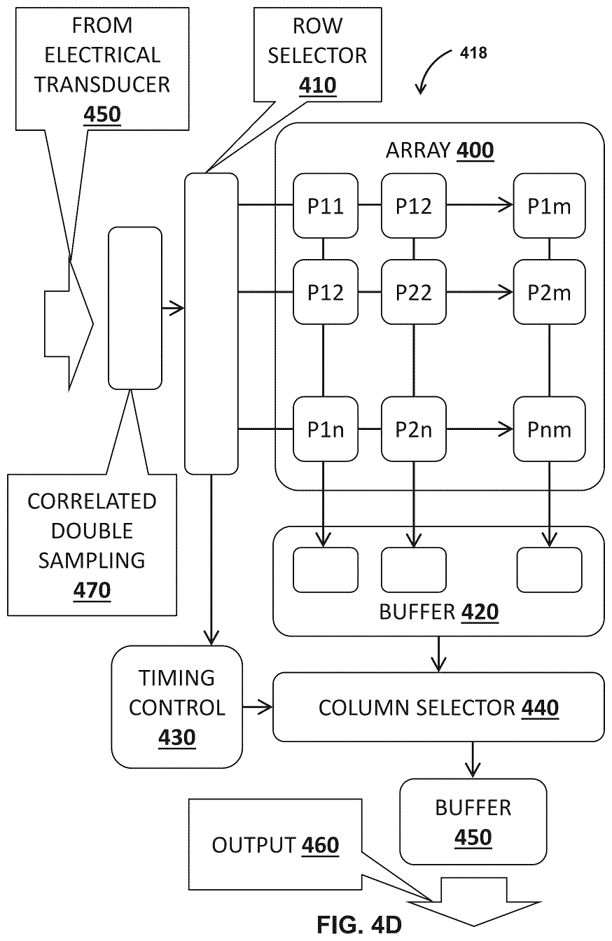

FIG. 4A is an example schematic representation of an analog device 412 to receive output integrated with an example analog optical interconnect. The analog device 412 may be the analog device 110b of FIG. 1. The analog device 412 may be an analog processor, accelerator (as of a partial application of a neural network), memory, etc. The analog device 412 may be a digital device, or partially digital device. The analog device 412 may be an analog device capable of operating on one or more digital signals. The analog device 412 may be a mixed signal sensor device (e.g., may receive as input both analog and digital signals). The analog device 412 may be or contain analog or mixed signal processing, such as circuitry for analog signal processing, circuitry for digital signal processing, circuitry for analog and digital signal processing. The analog device 412 may be a signal accelerator, including an accelerator which incorporates one or more element of a neural network, processing of a neural network, a kernel of a neural network, including elements described previously. The analog device 412 may be a memory, or contain memory, such as for storing signals of a sensor device (such as the analog device 110a of FIG. 1). The analog device 412 may receive a signal 450 from the electrical transducer, such as the electrical transducer 118 of FIG. 1 or the photodetector 340 of FIG. 3.

The analog device 412 may contain computing elements analogous to sensors of a sensor device (e.g., analogous to the pixels of the input analog device 202 of FIG. 2A or the input analog device 204 of FIG. 2B). The analog device 412 may be arranged in an array 400, which may correspond to an array (e.g., of sensors, pixels, sub-pixels, etc.) of an input device. The array 400, for example, may contain processing units P11-Pnm arranged in a two-dimensional array. The array 400 may instead or additionally contain a point array, one-dimensional array, a three-dimensional array, etc. The array 400 may contain more, fewer than, or the same amount or arrangement of pixels as an input device. Individual elements (e.g., processing units) of the array 400 may be selected, such as for storage of signals in memory (e.g., biased for writing) or for processing (e.g., selected for signal input) by operation of a row selector 410 and a column selector 440. The row selector 410 and the column selector 440 may be any appropriate signal selection device or operation, such as the signal selector 112b of FIG. 1.

The analog device 412 may contain a timing control unit 430, which may control the operation of the row selector 410 and the column selector 440. The timing control unit 430 may determine a row or column destination based on identifiers within (or before or after) received signals. The timing control unit 430 may receive signals from or be in communication with a timing control until for an input device (such as the timing control until 230 of FIGS. 2A and 2B) or control unit for the input device. The timing control unit 430 may operate based on one or more clocking signals, including a clocking signal for or output by the input device. The timing control unit 430 may generate a clocking signal, including generating a clocking signal based on a clocking signal of the input device.

The analog device 412 may contain one or more buffers, such as a buffer 420 which may buffer column output before application of the column selector 440 and a buffer 450 which may buffer output of the column selector 440. The one or more buffer may instead or additionally be an amplifier, including a TIA. The output of the analog device 412 may be output 460 to additional processing or memory, such as to a display, to a network interface for transmission to a cloud storage, to additional layers of a neural network, etc.

FIG. 4B is an example schematic representation of a RRAM analog device 414 to receive output integrated with an example analog optical interconnect. The RRAM analog device 414 is described in reference to elements previously described in reference to the analog device 412 of FIG. 4A, but may contain any appropriate circuitry. The RRAM analog device 414 may contain an array 402 of resistive elements R11-Rnm. Output of the array 402 may be processed by one or more amplifiers, such as amplifiers 422, before or after application of the column selector 440.

FIG. 4C is an example schematic representation of a SRAM analog device 416 to receive output integrated with an example analog optical interconnect. The SRAM analog device 416 is described in reference to elements previously described in reference to the analog device 412 of FIG. 4A and the RRAM analog device 414 of FIG. 4B, but may contain any appropriate circuitry. The SRAM analog device 416 may contain an array 404 of static elements S11-Snm, which may be composed of multiple flip-flop arrangements of transistors. Output of the array 404 may be processed by one or more amplifiers, such as the amplifiers 422, before or after application of the column selector 440.

FIG. 4D is an example schematic representation of an analog device with correlated double sampling 418 to receive output integrated with an example analog optical interconnect. The analog device with CDS 418 is described in reference to elements previously described in reference to the analog device 412 of FIG. 4A, but may contain any appropriate circuitry.

The analog device 418 may contain circuitry for correlated double sampling (CDS) such as a correlated double sampling (CDS) unit 470. The CDS unit 470 may include any appropriate circuitry for CDS, such as switches, comparators, memory, etc. The CDS unit 470 may compare a given output 450 of the electrical transducer to another output of the electrical transducer.

The CDS unit 470 may compare outputs of sensors, pixels, sub-pixels, etc. in the form of their corresponding electrical signals. The CDS unit 470 may compare outputs of multiple of sensors, pixels, sub-pixels—for example may compare outputs of columns of sensors in the form of their corresponding electrical signals. The CDS unit 470 may compare voltage outputs, may compare current outputs, etc. The CDS unit 470 may instead or additional include array level computations, such as addition, multiplication, cross-product, etc. of output of multiple electrical signals of an input device.

In some embodiments, the array 400 (and likewise the arrays 402 and 404) may include additional contain processing, computing, memory, etc. The array 400 may include memory, including ROM, RAM, RRAM, DRAM, etc. The array 400 may include circuitry which corresponds to one or more kernel. The array 400 may include circuitry which applies weighting to outputs of pixels (or other sensors), such as weighting corresponding to weights of one or more nodes of a neural network. The array 400 may include circuitry which configures the pixels to act as neurons of a neural network. The array 400 may include any appropriate accelerator circuitry, such as that described previously.

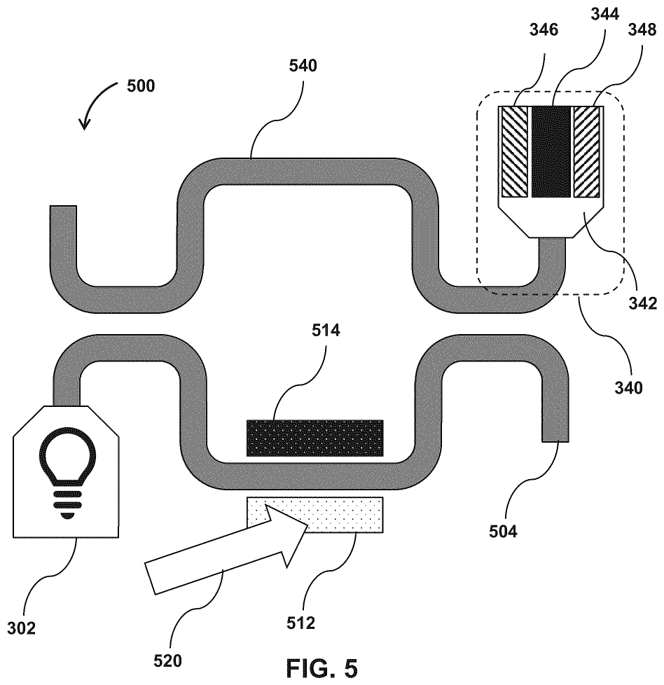

FIG. 5 is an example schematic representation of a phase-based analog electro-optical transducer 500 in an example analog optical interconnect. The analog electro-optical transducer 500 may also transduce digital signals. The analog electro-optical transducer 500 may contain an optical source 302, which may be any appropriate optical source such as previously described in reference to FIG. 3. The optical source 302 may provide an optical signal to a waveguide 504. The waveguide 504 may be any appropriate waveguide, such as a bus waveguide or both a bus and drop waveguide (including in different parts of the optical path). The waveguide 504 may be an integrated waveguide, such as a recessed waveguide in a silicon chip. The waveguide 504 may be an optical fiber and may be integrated, such as through V-groove integration, with a substrate. The waveguide 504 may be connected to one or more substrate by method described in U.S. Provisional Patent Application 63/442,703, filed 1 Feb. 2023, titled BACKSIDE OPTICAL COUPLER, the entire contents of each aforementioned patent filing is hereby incorporated by reference.

The waveguide 504 may provide an optical signal to a phase changing device, which may be a phase shifter. The phase shifter may be composed to one or more electrical contacts, such as a first electrical contact 512, which may be a p-contact or p-doped region of a semiconductor such as that in which the waveguide 504 is fabricated. The phase shifter may have a second contact 514, which may be an n-contact or n-doped region of a semiconductor, such as that in which the waveguide 504 is fabrication. An electrical signal, such as the output of the input analog device 202 of FIG. 2A or the input analog device 204 of FIG. 2B, may be applied, such as by input 520, to one or more contact of the phase shifter (e.g., the first contact 512, the second contact 514, etc.). The input may be applied to one contact while a second contact is grounded, electrically isolated, or otherwise has applied a constant or variable voltage, current, charge, etc. The phase shifter may have capacitive contacts. The phase shifter may alter a phase of an optical signal by heating, such as by resistive contacts.

The waveguide 504 may be in optical communication with an additional waveguide 540. The waveguide 504 may be in optical communication with the additional waveguide 540 in two or more locations, such as at a first location and a second location. The waveguide 504 and the additional waveguide may have the same or different optical path lengths between the various points of contact. The additional waveguide 540 may receive an optical signal from the waveguide 504 at a first location. The additional waveguide 540 may receive an additional optical signal from the waveguide 504 at the second location. Within the additional waveguide 540, the optical signal and the additional optical signal may interfere with one another, such as by constructive or destructive interference. The interference of the optical signal and the additional optical signal may be altered by application of a phase shift by the phase shifter of the waveguide 504. The interference of the optical signal and the additional optical signal may be detected (e.g., measured) by a photodetector, such as at a photodetector 340. The photodetector 340 may be any appropriate photodetector, such as described in reference to FIG. 3.

It should be understood that the analog input devices (such as input analog device 202 of FIG. 2A and the input analog device 204 of FIG. 2B) may be used with various of the analog devices 412 (of FIG. 4A), 414 (of FIG. 4B), 416 (of FIG. 4C) and 418 (of FIG. 4D), such as in configurations depicted in FIG. 1.

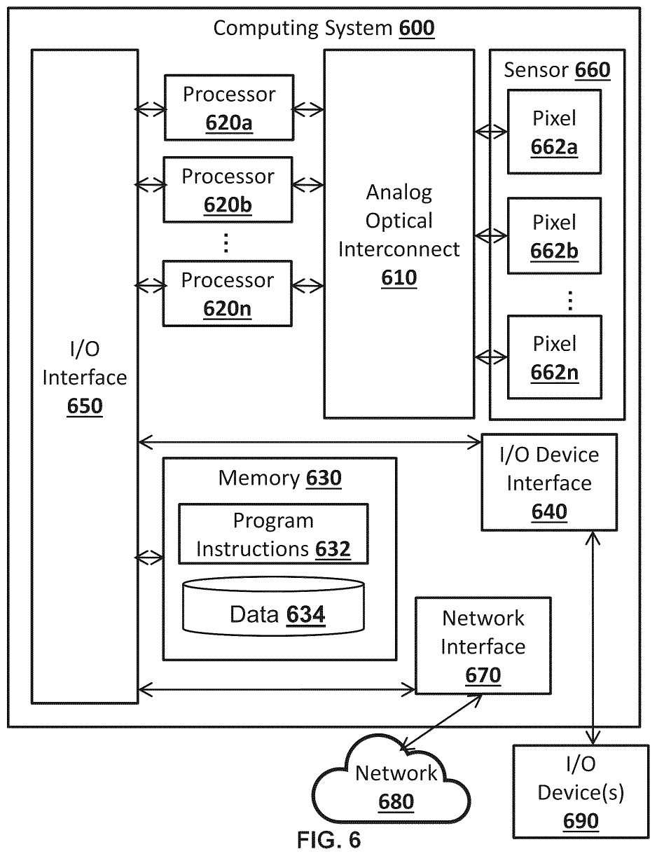

FIG. 6 illustrates an example computing system 600 using an analog optical interconnect. Various portions of systems and methods described herein may include or be executed on one or more computing systems similar to computing system 600. Further, processes and modules described herein may be executed by one or more processing systems similar to that of computing system 600.

Computing system 600 may include one or more processors (e.g., processors 620a-620n) coupled to system memory 630, a I/O interface 640, and a network interface 670 via an input/output (I/O) interface 650. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 600. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 630). Computing system 600 may be a uni-processor system including one processor (e.g., processor 620a-620n), or a multi-processor system including any number of suitable processors (e.g., 620a-620n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus may also be implemented as, special purpose logic circuitry, e.g., an FPGA (field programmable gate array) or an ASIC (application specific integrated circuit). Computing system 600 may include a plurality of computing devices (e.g., distributed computing systems) to implement various processing functions.

Computing system 600 may include a sensor 660, which may contain one or more pixels (e.g., pixels 662a-662n), coupled to an analog optical interconnect 610 and to one or more processors 620a-620n. The sensor 660 may be coupled, such as through the processors 620a-620n, to a system memory 630, and a user interface 640 via an input/output (I/O) interface 650. The pixels 662a-662n may be controlled by one or more reset element, such as a reset element (not depicted) in communication with the I/O interface 650 or controlled by one or more of the processors 620a-620n. The pixels 662a-662n may be exposed to input, such as light (e.g., in the case of a photosensor) or other input, an analyte (such as temperature), or other sensing material. The pixels 662a-662n may comprise transistors, diodes, etc.

Computing system 600 may include an analog optical interconnect 610, which may be coupled to pixels 662a-662n of the sensor 660 and provide communication from the pixels 662a-662n to the processors 620a-620n or memory 630, such as via the I/O interface 650. The analog optical interconnect 610 may be controlled by the processors 620a-620n, such as based on instructions stored in the memory 630. The analog optical interconnect 610 may include elements for digital optical communication.

The I/O device interface 640 may comprise one or more I/O device interface, for example to provide an interface for connection of one or more I/O devices 690 to computing system 600. The I/O device interface 640 may include devices that receive input (e.g., from a user) or output information (e.g., to a user). The I/O device interface 640 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. The I/O device interface 640 may be connected to computing system 600 through a wired or wireless connection. The user interface 640 may be connected to computing system 600 from a remote location. The user interface 640 may be in communication with one or more other computing systems. Other computing units, such as located on remote computer system, for example, may be connected to computing system 600 via a network 680, which may be connected via the network interface 670.

System memory 630 may be configured to store program instructions 632 or data 634. Program instructions 632 may be executable by a processor (e.g., one or more of processors 620a-620n) to implement one or more embodiments of the present techniques. Program instructions 632 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network, such as the network 680.

System memory 630 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard-drives), or the like. System memory 630 may include a non-transitory computer readable storage medium that may have program instructions stored thereon that are executable by a computer processor (e.g., one or more of processors 620a-620n) to cause the subject matter and the functional operations described herein. A memory (e.g., system memory 630) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 650 may be configured to coordinate I/O traffic between processors 620a-620n, analog optical interconnect 610, pixels 662a-662b, system memory 630, I/O device interface 640, etc. I/O interface 650 may perform protocol, timing, or other data transformations to convert data signals from one component (e.g., system memory 630) into a format suitable for use by another component (e.g., processors 620a-620n). I/O interface 650 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 600 or multiple computing systems 600 configured to host different portions or instances of embodiments. Multiple computing systems 600 may provide for parallel or sequential processing/execution of one or more portions of the techniques described herein.

Those skilled in the art will appreciate that computing system 600 is merely illustrative and is not intended to limit the scope of the techniques described herein. Computing system 600 may include any combination of devices or software that may perform or otherwise provide for the performance of the techniques described herein. For example, computing system 600 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 600 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 600 may be transmitted to computing system 600 via transmission media or signals such as electrical, electromagnetic, or digital signals, conveyed via a communication medium such as a network (e.g., the network 680) or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (e.g., meaning having the potential to), rather than the mandatory sense (e.g., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, e.g., encompassing both “and” and “or.” The term “each” does not require an exact relationship or that absolutely all elements thus described are involved, e.g., each may indicate substantially all and does not require participation of all elements identified as each. The term “each” may indicate a substantially one-to-one relationship, a one-to-many relationship, etc. Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B may include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, e.g., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and may be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques will be better understood with reference to the following enumerated embodiments:
1. A device, comprising: an analog optical interconnect; an input array coupled to the analog optical interconnect; and an analog or mixed signal processor or a memory array coupled to the input array via the analog optical interconnect.
2. The device of embodiment 1, further comprising: a row or column selector configured to connect the input array to the analog optical interconnect; and a column or row selector configured to connect the analog optical interconnect to the analog or mixed signal processor or the memory array.
3. The device of embodiment 1 or 2, wherein the analog optical interconnect comprises: a bus waveguide coupled to a laser; a drop waveguide coupled to a detector; and a ring resonator optically connecting the bus waveguide and the drop waveguide and having an n-contact and a p-contact.
4. The device of any one of embodiments 1 to 3, wherein the analog optical interconnect is a silicon analog optical interconnect.
5. The device of any one of embodiments 1 to 4, wherein the analog optical interconnect comprises a phase-based analog optical interconnect.
6. The device of embodiment 5, wherein the phase-based analog optical interconnect comprises: a waveguide coupled to a laser having an n-contact and a p-contact; and a waveguide coupled to a detector.
7. The device of any one of embodiments 1 to 6, wherein: the analog optical interconnect comprises a pair of waveguides configured to effect phase-based communication.
8. The device of any one of embodiments 1 to 7, comprising: the memory array, wherein the memory array is a resistive random access memory array.
9. The device of any one of embodiments 1 to 8, comprising: the memory array, wherein the memory array is a phase-change memory array.
10. The device of any one of embodiments 1 to 9, comprising: the memory array, wherein the memory array is a crossbar memory array.
11. The device of any one of embodiments 1 to 10, comprising: a static random access memory array based machine-learning accelerator coupled to the analog optical interconnect.
12. The device of any one of embodiments 1 to 10, comprising: an analog magnetic random access memory array based machine-learning accelerator coupled to the analog optical interconnect.
13. The device of any one of embodiments 1 to 12, comprising: an analog array based correlated double sampling sensor coupled to the analog optical interconnect.
14. The device of any one of embodiments 1 to 12, comprising: a correlated double sampling circuit coupling the analog optical interconnect to a machine-learning accelerator.
15. The device of any one of embodiments 1 to 14, wherein the input array is a pixel array.
16. The device of any one of embodiments 1 to 15, comprising: a complementary metal-oxide-semiconductor (CMOS) image sensor including the input array, wherein the CMOS image sensor comprises in-pixel computing circuits.
17. The device of any one of embodiments 1 to 16, wherein the input array is a sensor array.
18. The device of any one of embodiments 1 to 14, wherein the input array is a processor array.

1. A device, comprising:
an analog optical interconnect;
an input array coupled to the analog optical interconnect; and
an analog or mixed signal processor or a memory array coupled to the input array via the analog optical interconnect.

2. The device of claim 1, further comprising:
a row or column selector configured to connect the input array to the analog optical interconnect; and
a column or row selector configured to connect the analog optical interconnect to the analog or mixed signal processor or the memory array.

3. The device of claim 1, wherein the analog optical interconnect comprises:
a bus waveguide coupled to a laser;
a drop waveguide coupled to a detector; and
a ring resonator optically connecting the bus waveguide and the drop waveguide and having an n-contact and a p-contact.

4. The device of claim 1, wherein the analog optical interconnect is a silicon analog optical interconnect.

5. The device of claim 1, wherein the analog optical interconnect comprises a phase-based analog optical interconnect.

6. The device of claim 5, wherein the phase-based analog optical interconnect comprises:
a first waveguide coupled to a laser, the first waveguide having an n-contact and a p-contact, the n-contact and the p-contact configured to change an optical property of the first waveguide; and
a second waveguide coupled to a detector.

7. The device of claim 1, wherein:
the analog optical interconnect comprises a pair of waveguides configured to effect phase-based communication.

8. The device of claim 1, comprising:
the memory array, wherein the memory array is a resistive random access memory array.

9. The device of claim 1, comprising:
the memory array, wherein the memory array is a phase-change memory array.

10. The device of claim 1, comprising:
the memory array, wherein the memory array is a crossbar memory array.

11. The device of claim 1, comprising:
a static random access memory array based machine-learning accelerator coupled to the analog optical interconnect.

12. The device of claim 1, comprising:
an analog magnetic random access memory array based machine-learning accelerator coupled to the analog optical interconnect.

13. The device of claim 1, comprising:
an analog array based correlated double sampling sensor coupled to the analog optical interconnect.

14. The device of claim 1, comprising:
a correlated double sampling circuit coupling the analog optical interconnect to a machine-learning accelerator.

15. The device of claim 1, wherein the input array is a pixel array.

16. The device of claim 1, comprising:
a complementary metal-oxide-semiconductor (CMOS) image sensor including the input array, wherein the CMOS image sensor comprises in-pixel computing circuits.

17. The device of claim 1, wherein the input array is a sensor array.

18. The device of claim 1, wherein the input array is a processor array.

19. The device of claim 1, wherein the analog optical interconnect comprises:
a bus waveguide coupled to a laser;
a drop waveguide coupled to a detector, wherein the bus waveguide and the drop waveguide are optically connected at a first location and a second location; and
a phase shifter optically connected to the bus waveguide between the first location and the second location, the phase shifter having an n-contact and a p-contact.

20. An optical interconnect comprising:
an input signal selector configured to select one or more analog electrical signals;
a bus waveguide configured to receive an optical input signal;
an optical transducer configured to cause, based on the one or more analog electrical signals, transmission, by the bus waveguide, of an optical signal, the optical signal being generated from the optical input signal;
a drop waveguide in optical communication with the bus waveguide configured to receive the optical signal of the bus waveguide and to transmit the optical signal to a detector.

21. The optical interconnect of claim 20, further configured to transmit one or more analog electrical output signals based on the optical signal detected by the detector.

22. The optical interconnect of claim 20, wherein the optical interconnect receives and transmits analog signals.

23. The optical interconnect of claim 20, devoid of analog-to-digital (ADC) or digital-to-analog (DAC) conversion of electrical or optical signals.

24. The optical interconnect of claim 20, wherein the input signal selector is configured to select the one or more analog electrical signals from an input array and wherein the detector is configured to transmit one or more output analog electrical signals to an analog or mixed signal process or a memory array.

25. The optical interconnect of claim 24, wherein the optical interconnect connects cells of the input array to cells of the analog or mixed signal process or a memory array.

26. The optical interconnect of claim 24, wherein the input array is associated with a complementary metal-oxide-semiconductor (CMOS) image sensor, wherein the CMOS image sensor comprises in-pixel computing circuits and wherein the analog or mixed signal process or a memory array is associated with a machine-learning accelerator.

27. The optical interconnect of claim 20, comprising means for transferring analog data from a complementary metal-oxide-semiconductor (CMOS) image sensor to memory or a processor without digital conversion.

28. A method comprising:
selecting, from a plurality of analog electrical signals, one or more input analog electrical signals;
transmitting, by a bus waveguide, a first optical signal;
modulating, by an optical transducer based on the one or more input analog electrical signals, the first optical signal to generate a second optical signal;
receiving, by a drop waveguide, the second optical signal and transmitting the second optical signal to a detector, wherein the drop waveguide is in optical communication with at least a portion of the bus waveguide.

29. The method of claim 28, further comprising transmitting one or more analog electrical output signals based on the second optical signal detected by the detector.

30. The method of claim 28, without analog-to-digital (ADC) or digital-to-analog (DAC) converting of electrical or optical signals.

31. The method of claim 28, comprising steps for transferring data from a plurality of pixels of a complementary metal-oxide-semiconductor (CMOS) image sensor to a plurality of cells of a processer or memory without analog to digital (ADC) conversion.
